(19) United States
(12) Patent Application Publication
(10) Pub. No.: US 2008/0169499 A1
(43) Pub. Date: Jul. 17, 2008

(54) FLASH MEMORY USING STI STRUCTURE IN ELEMENT ISOLATION REGION AND MANUFACTURING METHOD THEREOF

(76) Inventor: Masahiro KIYOTOSHI, Sagamihara-shi (JP)

Correspondence Address: FINNEGAN, HENDERSON, FARABOW, GARRETT & DUNNER;LLP, 901 NEW YORK AVENUE, NW, WASHINGTON, DC, 20001-4413, US

(21) Appl. No.: 12/014,869

(22) Filed: Jan. 16, 2008

(30) Foreign Application Priority Data
Jan. 17, 2007 (JP) 2007-008081

(51) Int. Cl. H01L 29/788; H01L 21/336

(52) U.S. Cl. 257/316; 438/257; 257/E29.3; 257/E21.422

(57) ABSTRACT

A flash memory includes a memory cell portion and peripheral circuit portion. The memory cell portion has first gate dielectric films formed on the main surface of a semiconductor substrate and floating gate electrode layers formed on the first gate dielectric films. The peripheral circuit portion has second gate dielectric films formed on the main surface of the semiconductor substrate and gate electrode layers formed on the second gate dielectric films. The penetration depth of a bird's beak formed in contact with the upper and bottom surfaces of the second gate dielectric film is larger than the penetration depth of a bird's beak formed in contact with the upper and bottom surfaces of the first gate dielectric film.

### CROSS-REFERENCE TO RELATED APPLICATIONS

This application is based upon and claims the benefit of priority from prior Japanese Patent Application No. 2007-008081, filed Jan. 17, 2007, the entire contents of which are incorporated herein by reference.

### BACKGROUND OF THE INVENTION

1. Field of the Invention

This invention relates to a flash memory using a shallow trench isolation structure in an element isolation region and a manufacturing method thereof.

2. Description of the Related Art

Recently, flash memories are aggressively shrinked to reduce the bit cost due to the higher integration density. Flash memories with the minimum half pitch of 70 nm at the mass-production level are produced and the technical difficulty becomes high. However, it is planned that flash memories are to be further shrinked in the future and devices with the size scaled down to approximately 50 nm are experimentally manufactured at the development stage.

It therefore becomes difficult to process the element without degrading the characteristics of cells which are scaled down with the rapid device shrinkage and a peripheral circuit portion which is not required to be shrinked to such an extent as the cells.

Conventionally, silicon thermal oxide films (which are hereinafter referred to as active area oxide films) are formed by oxidizing the exposed sidewalls of an active area after isolation trenches with the shallow trench isolation structure are formed. The purpose of providing the active area oxide film is to remove defects of the end portions of the active area by the STI processing and alleviate the electric field concentration by rounding the edge of the active area, for example. Since a high-voltage circuit portion which is required to perform the high-voltage operation of 30V or more is provided in the peripheral circuit portion of the flash memory, it is preferable to perform a sufficiently rounding oxidation process in order to alleviate the electric field concentration by oxidizing the active area (for example, refer to Jpn. Pat. Appln. KOKAI Publication No. 2002-141408 and U.S. Pat. No. 6,509,232).

In the memory cell portion, if the half pitch is reduced from 45 nm to 32 nm in the future, a “reduction” in the thickness of the active area due to oxidation of the side surfaces of the active area enhances the narrow channel effect. Further, the gate oxide film thickness of the memory cell portion is effectively increased by bird's beak oxidation caused by oxidizing agents diffusion during the oxidation of the side surfaces of the active area and there occurs a problem that the write/erase voltage of the flash memory increases and the write/erase speed thereof is lowered.

In order to cope with the problem that the requirements for oxidation of the active area in the memory cell portion and peripheral circuit portion are different, it is considered to separately perform the oxidation processes for active areas by separately forming STI regions in the memory cell portion and peripheral circuit portion.

However, by thus performing the above process, the number of lithography steps is doubled and the process with a large numerical aperture (NA) is required for the peripheral circuit portion in order to fit the peripheral circuit portion to the memory cell portion which is required to be processed with the minimum half pitch size. As a result, there occurs a problem that the number of process steps is greatly increased.

### BRIEF SUMMARY OF THE INVENTION

According to a first aspect of the present invention, there is provided a flash memory which includes a memory cell portion having first gate dielectric films formed on the main surface of a semiconductor substrate and floating gate electrode layers formed on the first gate dielectric films, and a peripheral circuit portion having second gate dielectric films formed on the main surface of the semiconductor substrate and gate electrode layers formed on the second gate dielectric films, wherein the penetration depth of a bird's beak formed in contact with the upper surface and bottom surface of the second gate dielectric film is larger than the penetration depth of a bird's beak formed in contact with the upper surface and bottom surface of the first gate dielectric film.

According to a second aspect of the present invention, there is provided a manufacturing method of a flash memory which includes forming a first isolation trench for element isolation of a memory cell portion having first gate dielectric films and floating gate electrode layers and a second isolation trench having a larger width in a gate width direction than the first isolation trench, for element isolation of a peripheral circuit portion having second gate dielectric films and gate electrode layers in the main surface of a semiconductor substrate, depositing a liner dielectric film to partly or completely fill the first isolation trench and partly fill the second isolation trench, making the penetration depth of a bird's beak formed in contact with the upper surface and bottom surface of the second gate dielectric film larger than the penetration depth of a bird's beak formed in contact with the upper surface and bottom surface of the first gate dielectric film by oxidizing the semiconductor substrate and gate electrode layers via the liner dielectric film deposited in the second isolation trench to form a silicon oxide film, and forming a gap-fill film on the liner dielectric film after forming the silicon oxide film.

### BRIEF DESCRIPTION OF THE SEVERAL VIEWS OF THE DRAWING

FIG. 1 is a cross sectional view showing one manufacturing step of a manufacturing method of a semiconductor device according to a first embodiment of this invention;

FIG. 2 is a cross sectional view showing one manufacturing step of the manufacturing method of the semiconductor device following the step of FIG. 1;

FIG. 3 is a cross sectional view showing one manufacturing step of the manufacturing method of the semiconductor device following the step of FIG. 2;

FIG. 4 is a cross sectional view showing one manufacturing step of the manufacturing method of the semiconductor device following the step of FIG. 3;

FIG. 5 is a cross sectional view showing one manufacturing step of the manufacturing method of the semiconductor device following the step of FIG. 4;

FIG. 6 is a diagram showing a variation in the increase amount of an oxide film thickness by plasma oxidation when the initial oxide film thickness (the film thickness of a liner dielectric film) is different;

FIG. 7 is a diagram showing the relationship between the trench width after deposition of the liner dielectric film and the penetration depth of bird's beaks formed along the upper and lower interfaces of a gate dielectric film;

FIG. 8 is a cross sectional view showing one manufacturing step of the manufacturing method of the semiconductor device following the step of FIG. 5;

FIG. 9 is a cross sectional view showing one manufacturing step of the manufacturing method of the semiconductor device following the step of FIG. 8;

FIG. 10 is a cross sectional view showing one manufacturing step of the manufacturing method of the semiconductor device following the step of FIG. 9;

FIG. 11 is a cross sectional view showing one manufacturing step of the manufacturing method of the semiconductor device following the step of FIG. 10;

FIG. 12 is a cross sectional view showing one manufacturing step of the manufacturing method of the semiconductor device following the step of FIG. 11;

FIG. 13 is a cross sectional view showing one manufacturing step of the manufacturing method of the semiconductor device following the step of FIG. 12;

FIG. 14 is a cross sectional view showing one manufacturing step of the manufacturing method of the semiconductor device following the step of FIG. 13;

FIG. 15 is a cross sectional view showing one manufacturing step of the manufacturing method of the semiconductor device following the step of FIG. 14;

FIG. 16 is a cross sectional view showing one manufacturing step of a manufacturing method of a semiconductor device according to a second embodiment of this invention;

FIG. 17 is a cross sectional view showing one manufacturing step of the manufacturing method of the semiconductor device following the step of FIG. 16;

FIG. 18 is a cross sectional view showing one manufacturing step of the manufacturing method of the semiconductor device following the step of FIG. 17;

FIG. 19 is a cross sectional view showing one manufacturing step of the manufacturing method of the semiconductor device following the step of FIG. 18;

FIG. 20 is a cross sectional view showing one manufacturing step of the manufacturing method of the semiconductor device following the step of FIG. 19;

FIG. 21 is a cross sectional view showing one manufacturing step of the manufacturing method of the semiconductor device following the step of FIG. 20;

FIG. 22 is a cross sectional view showing one manufacturing step of the manufacturing method of the semiconductor device following the step of FIG. 21;

FIG. 23 is a cross sectional view showing one manufacturing step of the manufacturing method of the semiconductor device following the step of FIG. 22;

FIG. 24 is a cross sectional view showing one manufacturing step of the manufacturing method of the semiconductor device following the step of FIG. 23;

FIG. 25 is a cross sectional view showing one manufacturing step of the manufacturing method of the semiconductor device following the step of FIG. 24;

FIG. 26 is a cross sectional view showing one manufacturing step of the manufacturing method of the semiconductor device following the step of FIG. 25;

FIG. 27 is a cross sectional view showing one manufacturing step of the manufacturing method of the semiconductor device following the step of FIG. 26;

FIG. 28 is a cross sectional view showing one manufacturing step of the manufacturing method of the semiconductor device following the step of FIG. 27;

FIG. 29 is a cross sectional view showing one manufacturing step of the manufacturing method of the semiconductor device following the step of FIG. 28;

FIG. 30 is a cross sectional view showing one manufacturing step of a manufacturing method of a semiconductor device according to a third embodiment of this invention;

FIG. 31 is a cross sectional view showing one manufacturing step of the manufacturing method of the semiconductor device following the step of FIG. 30;

FIG. 32 is a cross sectional view showing one manufacturing step of the manufacturing method of the semiconductor device following the step of FIG. 31;

FIG. 33 is a cross sectional view showing one manufacturing step of the manufacturing method of the semiconductor device following the step of FIG. 32;

FIG. 34 is a cross sectional view showing one manufacturing step of the manufacturing method of the semiconductor device following the step of FIG. 33; and

FIG. 35 is a cross sectional view showing one manufacturing step of the manufacturing method of the semiconductor device following the step of FIG. 34.

### DETAILED DESCRIPTION OF THE INVENTION

### First Embodiment

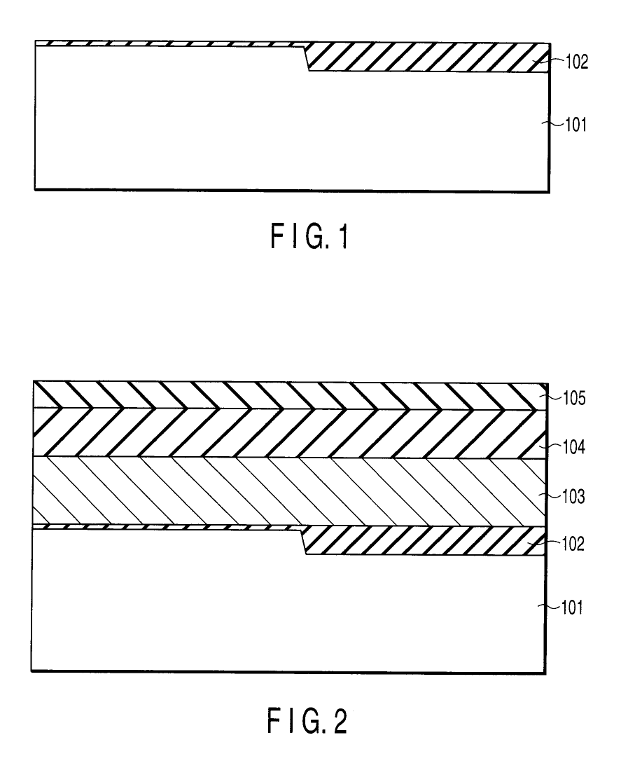

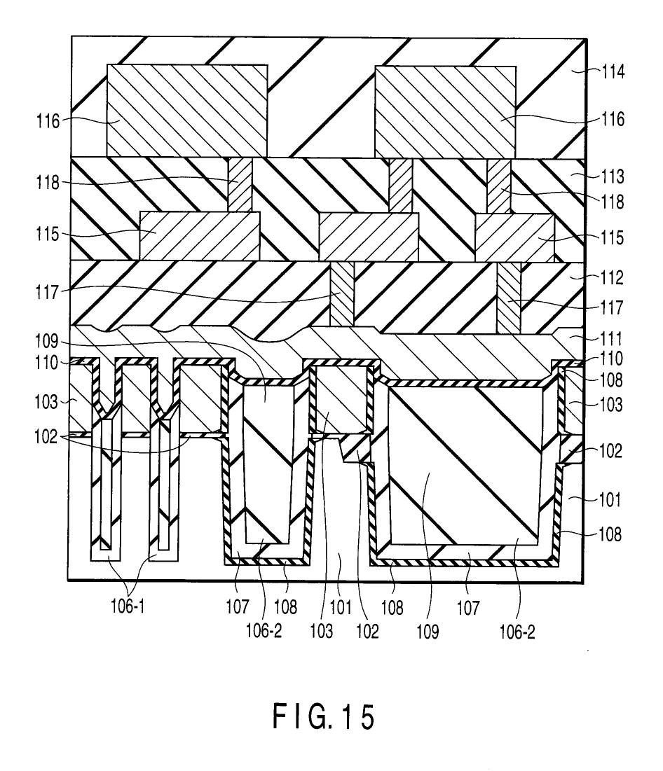

A manufacturing method of a flash memory according to a first embodiment of this invention is explained with reference to FIGS. 1 to 15. In the present embodiment, a memory cell portion of the flash memory is previously covered with a CVD silicon oxide film, the side surfaces of an active area of the peripheral circuit portion are oxidized and then an STI structure of the memory cell portion is formed.

First, as shown in FIG. 1, a silicon thermal oxynitride film 102 used as a gate dielectric film is formed to separately have the film thickness of 8 nm (first gate dielectric film) in a memory cell portion and the film thickness of 40 nm (second gate dielectric film) in a high-voltage circuit of a peripheral circuit on a semiconductor substrate 101 by use of a known lithography process and etching process.

Then, as shown in FIG. 2, a P-doped polysilicon film 103 (floating gate electrode layer) used as a floating gate is formed to the film thickness of 90 nm and a silicon nitride film 104 used as a polishing stopper of the CMP process is formed to the film thickness of 70 nm. Further, a CVD silicon oxide film 105 used as a mask for reactive ion etching (RIE) is formed on the entire surface of the resultant semiconductor structure and a photoresist film (not shown) is coated thereon.

Next, the photoresist film is exposed and developed by a normal lithography technique to form a photoresist pattern and the CVD silicon oxide film 105 is etched by use of an RIE process with the photoresist pattern used as a mask to form a hard mask (not shown). Then, the photoresist pattern is etched and removed by use of both ashing and wet treatment using a mixed solution of sulfuric acid and hydrogen peroxide solution.

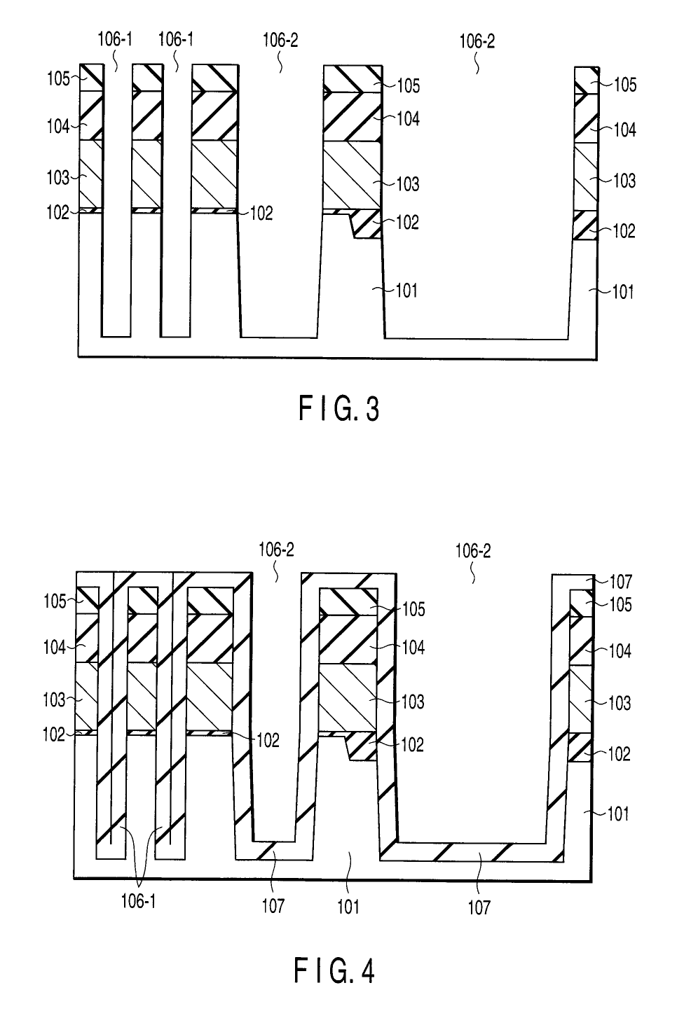

After this, as shown in FIG. 3, the silicon nitride film 104, P-doped polysilicon film 103, silicon thermal oxynitride film 102 and semiconductor substrate 101 are sequentially etched by use of the RIE process using the hard mask of the CVD silicon oxide film 105 to form isolation trenches 106-1 and 106-2 with the etching depth of 220 nm in the semiconductor substrate. The isolation trenches 106-1 and 106-2 configure STI regions. The STI width of the isolation trench 106-1 in the memory cell portion is set to 45 nm and the STI width of the isolation trench 106-2 in the peripheral circuit portion is set to 100 nm or more.

Next, as shown in FIG. 4, a silicon oxide film 107 (liner dielectric film) is deposited and formed to the film thickness of 25 nm on the entire surface of the resultant semiconductor structure by a CVD method using silane and N₂O as a raw material. As a result, the internal portion of the isolation trench 106-1 is almost completely filled with the silicon oxide film 107 and the entire surface of the isolation trench 106-2 is covered with the silicon oxide film 107.

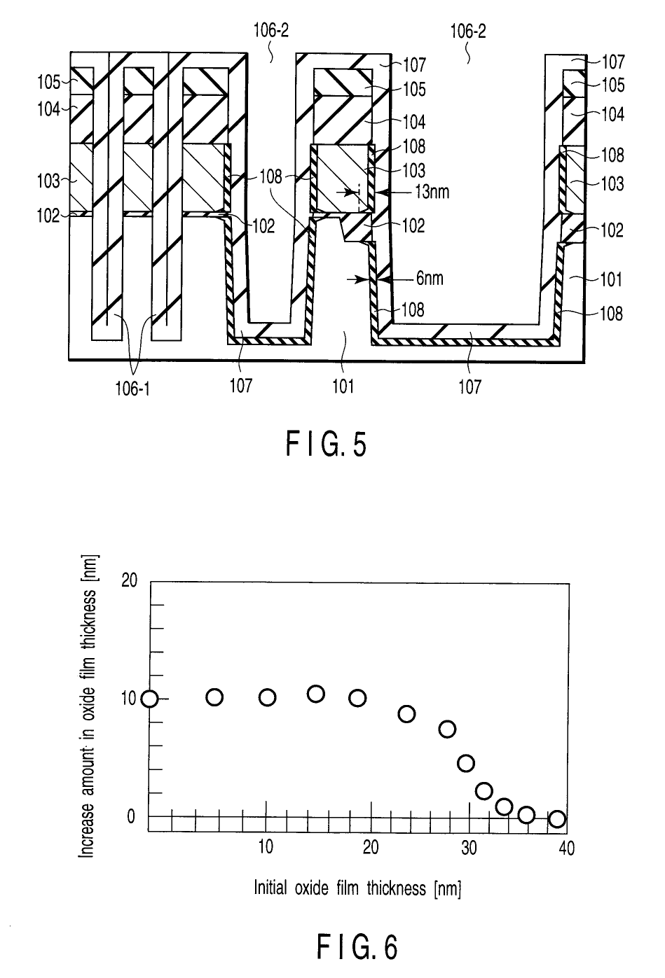

Then, as shown in FIG. 5, silicon oxide films 108 with the film thickness of 6 nm are formed on the semiconductor substrate 101 and the side walls of the P-doped polysilicon films 103 through the silicon oxide film 107 by plasma oxidation. The plasma oxidation process was performed under a condition that the films were formed with the film thickness of 6 nm on a test piece (bare silicon wafer) at the temperature of 850° C. by active oxygen excited by ICP (induction coupling plasma). The oxide film 108 formed by oxidizing the underlying semiconductor substrate 101 and P-doped polysilicon film 103 has a higher density in comparison with the silicon oxide film 107 formed by deposition by use of the CVD method.

The plasma oxidation process is performed by use of active oxygen, which is an oxidizing agent, through the silicon oxide film 107. If the active oxygen is diffused to the depth of 30 nm or more in the silicon oxide film formed by the CVD method, the active oxygen is deactivated. That is, the active oxygen loses oxidation capability as an oxidizing agent. This is also clearly understood from FIG. 6.

FIG. 6 indicates the initial oxide film thickness dependence of the silicon oxide thickness increase after the plasma oxidation through the CVD silicon oxide film, that is, the film thickness of the silicon oxide film 107 of the present embodiment on the abscissa and an increase amount of the film thickness by the presence of the oxide film 108 formed by the plasma oxidation process on the ordinate. As shown in FIG. 6, when the oxide film thickness of the silicon oxide film 107 formed by the CVD method exceeds 30 nm, the active oxygen is deactivated and an increase amount of the film thickness becomes almost zero.

In the present embodiment, the silicon oxide film 107 is formed to have the film thickness of 25 nm, which is less than 30 nm, but the initial trench width of the isolation trench 106-1 of the memory cell portion is 45 nm. Therefore, as shown in FIG. 4, the internal portion of the isolation trench 106-1 is almost completely filled with the silicon oxide film 107.

Since the oxidizing agent can reach the side walls of the active area without being deactivated in the peripheral circuit portion, the oxide films 108 are formed on the side walls of the active area under the silicon oxide film 107 in the isolation trench 106-2 as shown in FIG. 5. At the same time, the oxide films 108 penetrate along the interface between the silicon thermal oxynitride film 102 and the semiconductor substrate 101 and the interface between the silicon thermal oxynitride film 102 and the P-doped polysilicon film 103 and so-called bird's beaks are formed. The penetration length of the bird's beak in the active area end portion in the peripheral circuit at this time is set to 13 nm as shown in FIG. 5.

However, in the memory cell portion, since the internal portion of the isolation trench 106-1 is almost completely filled with the silicon oxide film 107, active oxygen cannot reach the side walls of the active area. Therefore, part of the surface of the silicon nitride film 104 is oxidized, but portions of the silicon substrate 101 which face the isolation trenches 106-1 are almost completely unoxidized.

As described above, in the first embodiment, a thick oxide film can be formed only on the side walls of the active area of the peripheral circuit portion without substantially forming the oxide film by plasma oxidation on the side walls of the active area of the memory cell portion, and the active area edge can be formed in a rounded form by the presence of the bird's beak oxidation.

Since the active oxygen used as the oxidizing agent in the plasma oxidation process is ionized by a plasma source to have a charge and is set into an excited state, the active oxygen is deactivated due to the interaction with the side surfaces of the trench in the narrow trench. Therefore, as in the present embodiment, even when non-filled portions are formed in a slit form in the cell internal portion without almost completely filling the internal portion of the isolation trench 106-1 with the silicon oxide film 107, substantially the same effect can be attained.

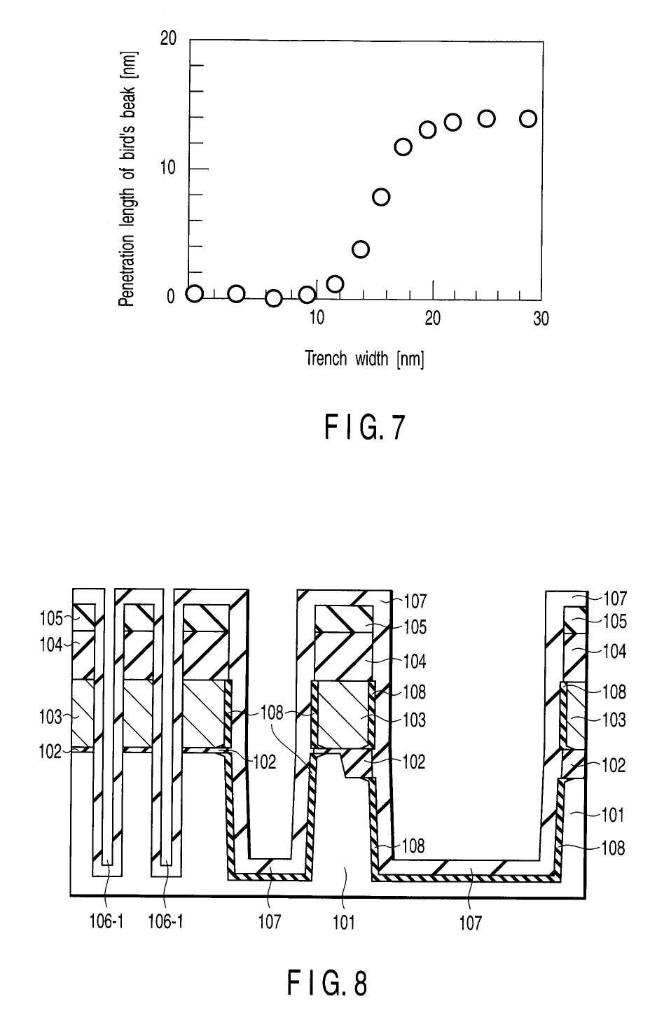

The correlation as shown in FIG. 7 is provided between the trench width after the silicon oxide film 107 is deposited and the penetration length of the bird's beaks formed along the upper and lower interfaces of the gate dielectric film. Therefore, formation of the bird's beak can be suppressed by setting the width of a non-filled region of the memory cell portion after deposition of the silicon oxide film 107 (the width of the open space in the isolation trench 106-1 after deposition of the silicon oxide film 107) to 10 nm or less.

Further, in the plasma oxidation process, ions of the oxidizing agent collide with one another and are deactivated under high pressure. Therefore, it is important to make it difficult for the oxidizing agent to diffuse by narrowing the width of the non-filled region of the memory cell portion and, at the same time, suppress growth of the oxide film in the trench by selecting the above condition (high pressure condition).

In the first embodiment, the silicon oxide film 107 (liner dielectric film) is deposited without forming a thermal oxide film on the underlying layer formed of the semiconductor substrate 101 and P-doped polysilicon film 103. However, before deposition of the silicon oxide film 107, the semiconductor substrate 101 and P-doped polysilicon film 103 can be thermally oxidized to such an extent that bird's beak oxidation will not cause a problem. This is because the thermal oxidation for the underlying layer has the effect that organic materials or the like on the silicon surface can be eliminated by oxidation and cleaned. Even in such a case, since bird's beak oxide regions can be formed with a larger thickness and depth only in the peripheral circuit portion by performing plasma oxidation through the silicon oxide film 107, the effect of enhancement of the breakdown voltage owing to rounding the end portions of the active area can be expected.

After formation of the oxide films 108 shown in FIG. 5, the seam portion (joint portion) of the silicon oxide film 107 filled in the memory cell portion is eliminated and the top of the trenches 106-1 are opened again by etching the silicon oxide film 107 by the width of approximately 5 nm by wet etching as shown in FIG. 8.

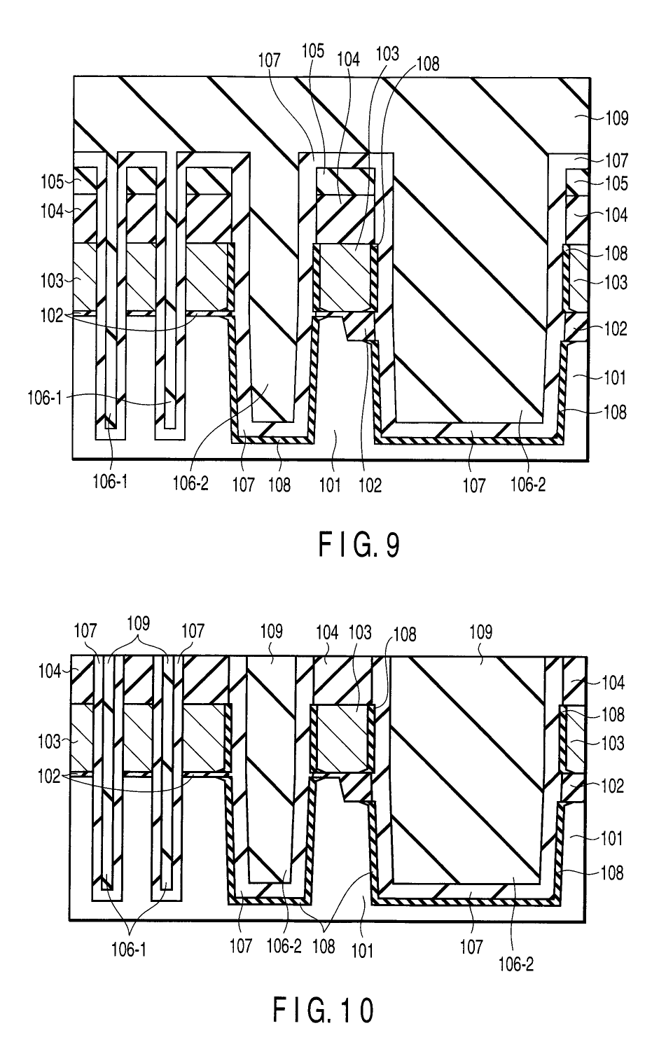

Next, as shown in FIG. 9, a polysilazane film 109 is formed on the entire surface of the resultant semiconductor structure and the isolation trenches 106-1 and 106-2 are completely filled. The polysilazane film is a gap-fill film having fluidity at the deposition.

Formation of the polysilazane film 109 is performed as follows.

A perhydro-polysilazane (PHPS) [(SiH₂NH)ₙ] whose mean molecular weight is 2000 to 6000 is dispersed into xylene, dibutylether and the like to form a PHPS solution. Then, the PHPS solution is coated on the surface of the semiconductor substrate 101 by a spin coating method.

Since the liquid is coated, the PHPS is filled into the internal portion of the isolation trench 106-1 having a narrow width of approximately 10 nm, as in the present embodiment, without forming voids (non-filled portions) and seam portions (joint-form non-filled portions). The conditions of the spin coating method are a rotation speed of the semiconductor substrate 101 of 1200 rpm, a rotation time of 30 seconds, a drop amount of the PHPS solution of 2 cc and a target coating film thickness immediately after baking of 450 nm.

Next, the semiconductor substrate 101 having the coating film formed thereon is heated to 150° C. on a hot plate and baked for three minutes in an inert gas atmosphere to vaporize a solvent in the PHPS solution. In this state, a carbon- or hydrocarbon-based material contained in the solvent remains, at a level of approximately several percent to around ten percent, as an impurity in the coating film. In this case, the perhydropolysilazane film is set in a state approximately equal to the state of a silicon nitride film containing a residual solvent and having a low density.

C, N remaining in the film are removed by performing a low-pressure steam oxidation process for one hour with a temperature of 250° C. and pressure of 400 Torr with respect to the polysilazane film thus formed. Further, the annealing process is performed in an inert gas atmosphere of 800° C. to 1000° C. to enhance the density of the polysilazane film.

Next, as shown in FIG. 10, the CVD silicon oxide film 105, silicon oxide film 107 and polysilazane film 109 are polished by use of the CMP technique with the silicon nitride film 104 used as a stopper. As a result, the polysilazane films 109 remain only in the internal portions of the isolation trenches 106-1 and 106-2.

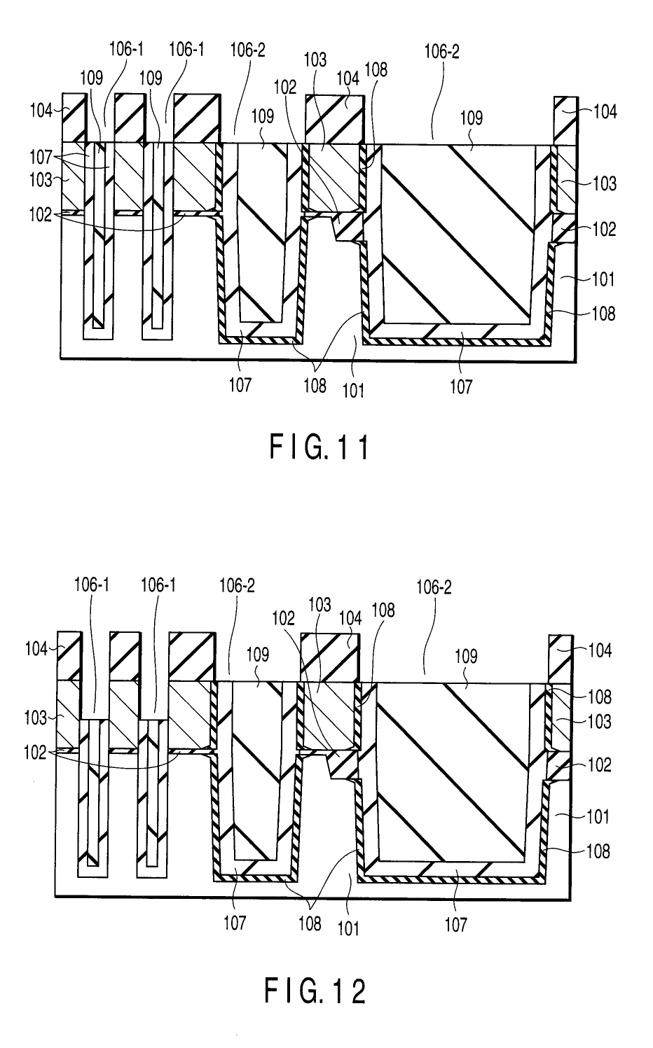

Then, as shown in FIG. 11, the gap-fill films (silicon oxide films 107 and polysilazane films 109) remaining in the internal portions of the isolation trenches 106-1, 106-2 are etched back by 70 nm by reactive ion etching.

Further, as shown in FIG. 12, the internal portion of the isolation trench 106-1 used as the STI region of the memory cell portion is further etched by 50 nm by use of a known lithography technique and RIE technique.

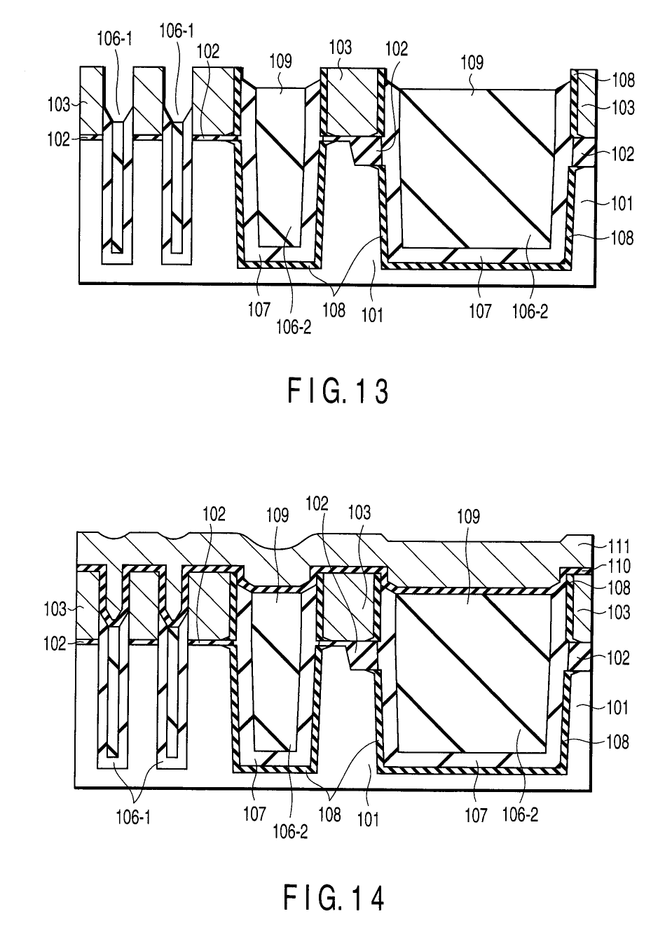

After this, as shown in FIG. 13, the STI regions in the memory cell portion and peripheral circuit portion are formed by removing the silicon nitride film 104 in hot phosphoric acid. In this case, the upper potions of the polysilazane films 109 are slightly recessed as shown in FIG. 13 due to a difference in the etching rate of the silicon oxide film 107 and polysilazane film 109 in the hot phosphoric acid.

Next, as shown in FIG. 14, an ONO film 110 used as an inter-polysilicon gate dielectric film (IPD) is formed and a P-doped polysilicon film 111 used as a control gate is formed. The P-doped polysilicon film 111, ONO film 110 and P-doped polysilicon film 103 are sequentially etched by use of a known lithography technique and RIE technique to form control gates and floating gates (not shown).

After this, the final structure of the device is obtained by forming interlayer dielectric films (ILD) 112, 113, 114 and a multi-layered wiring structure having wirings 115, 116, and contact plugs 117, 118 although a detailed explanation of the steps is omitted.

In the present embodiment, the phenomenon that the oxidizing agent in the plasma oxidation is deactivated during diffusion and the oxidation rate is rapidly lowered is utilized. That is, the oxidation process can be performed to form a thick oxide film on the side walls of the active area in the peripheral circuit portion in which the distance over which the oxidizing agent is required to diffuse is set short and prevent the side walls of the active area in the memory cell portion in which the distance is set long from being substantially oxidized.

In practice, in the subsequent process steps after the plasma oxidation process, there is a possibility that a minute bird's beak may be formed in the memory cell portion. However, even if it is taken into consideration, the penetration depth of the bird's beak formed in the peripheral circuit portion can be made larger than the penetration depth of the bird's beak formed in the memory cell portion by use of the method of the present embodiment. As a result, an oxide structure having shapes of the active area end portions which are different in the memory cell portion and peripheral circuit portion can be realized.

Therefore, the size of the bird's beak in the memory cell portion can be made small to prevent the write/erase characteristic from being deteriorated and, at the same time, the bird's beak can be formed deep into the active area end portion in the peripheral circuit portion to round the end portion of the active area and suppress the electric field concentration caused by the shape of the active area end portion. Thus, since a flash memory having a preferable cell characteristic and preferable peripheral circuit characteristic can be manufactured when an extremely narrow STI structure is formed, the bit density of the flash memory can be enhanced by further shrinkage of the flash memory.

In the present embodiment, the polysilazane film is used as a film which can be completely filled into the trench used as the STI region having the small width of 45 nm without forming voids. However, the STI trench with the small width can be filled by use of a different type of SOG film, for example, an HSQ (Hydrogen Silses Quioxane: HSiO_{3/2})ₙ, where n is an integral number) film or chemical vapor condensation film.

### Second Embodiment

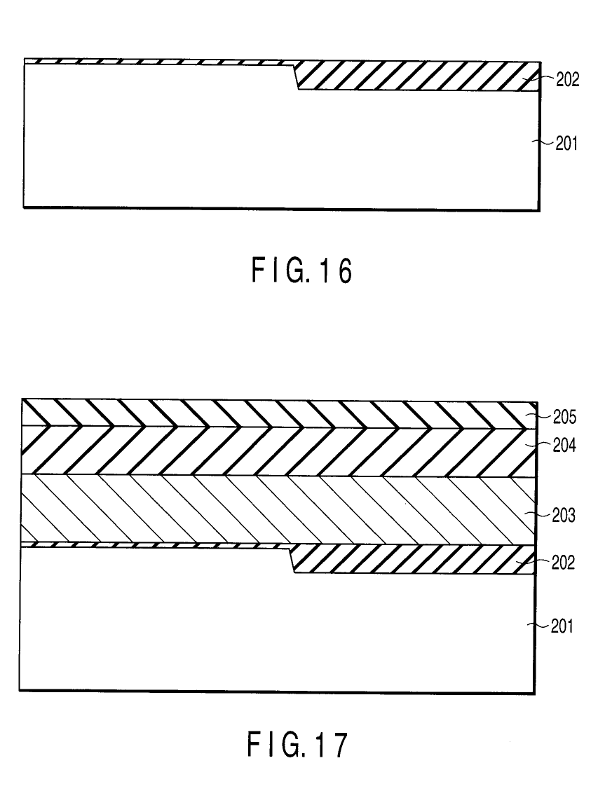

A manufacturing method of a flash memory according to a second embodiment of this invention is explained with reference to FIGS. 16 to 29. In the present embodiment, a thick oxide film is formed only on the side walls of an active area of a peripheral circuit portion, like the first embodiment, but a silicon oxide film (liner dielectric film) used as a mask when the side walls of the active area are subjected to radical oxidation is also used as a mask for tilted ion implantation.

First, as shown in FIG. 16, a silicon thermal oxynitride film 202 used as a gate dielectric film is formed to separately have the film thickness of 8 nm (first gate dielectric film) in a memory cell portion and the film thickness of 40 nm (second gate dielectric film) in a high-voltage circuit of a peripheral circuit on a semiconductor substrate 201 by use of a known lithography process and etching process.

Then, as shown in FIG. 17, a P-doped polysilicon film 203 (floating gate electrode layer) used as a floating gate is formed to the film thickness of 120 nm and a silicon nitride film 204 used as a polishing stopper of the CMP process is formed to the film thickness of 100 nm. Further, a CVD silicon oxide film 205 used as a mask for reactive ion etching (RIE) is formed on the entire surface of the resultant semiconductor structure and a photoresist film (not shown) is coated thereon.

Next, the photoresist film is exposed and developed by a normal lithography technique to form a photoresist pattern and the CVD silicon oxide film 205 is etched by use of the RIE process with the photoresist pattern used as a mask to form a hard mask (not shown). The photoresist pattern is etched and removed by both ashing and wet treatment using a mixed solution of sulfuric acid and hydrogen peroxide solution.

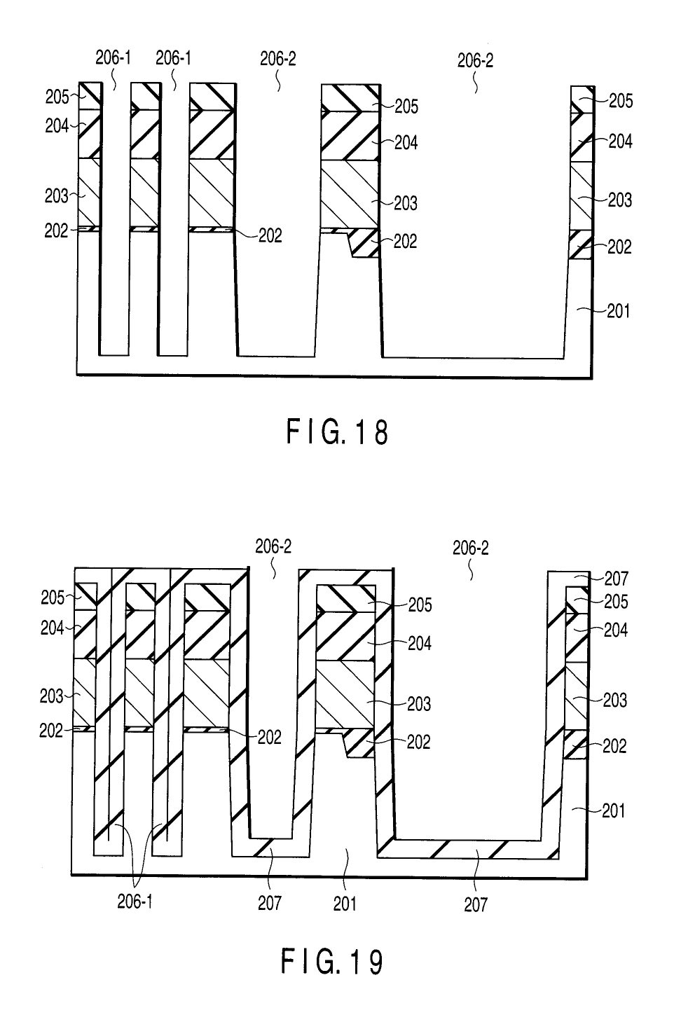

After this, as shown in FIG. 18, the silicon nitride film 204, P-doped polysilicon film 203, silicon thermal oxynitride film 202 and semiconductor substrate 201 are sequentially etched by use of the RIE process using the hard mask of the CVD silicon oxide film 205 to form isolation trenches 206-1 and 206-2 with the etching depth of 220 nm in the semiconductor substrate. The isolation trenches 206-1 and 206-2 configure STI regions. The STI width of the isolation trench 206-1 in the memory cell portion is set to 32 nm and the STI width of the isolation trench 206-2 in the peripheral circuit portion is set to 100 nm or more.

Next, as shown in FIG. 19, a silicon oxide film 207 (liner dielectric film) is deposited and formed to the film thickness of 15 nm on the entire surface of the resultant semiconductor structure by a CVD method using TEOS (Tetra Ethoxy Silane) as a raw material. As a result, the internal portion of the isolation trench 206-1 is almost completely filled with the silicon oxide film 207 and the entire surface of the isolation trench 206-2 is also covered with the silicon oxide film 207.

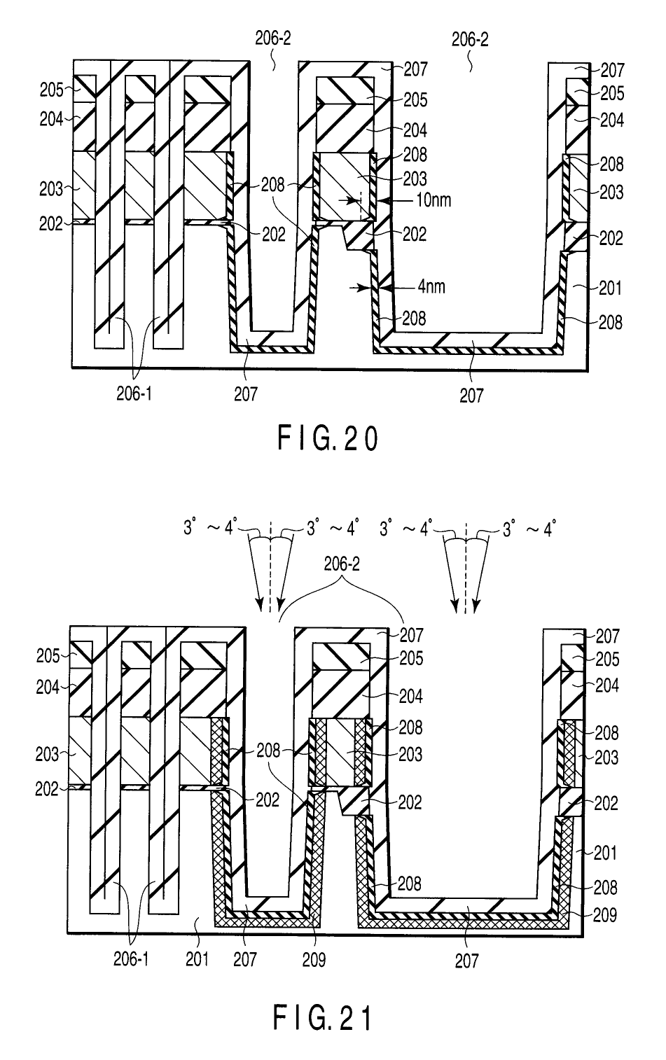

Then, as shown in FIG. 20, silicon oxide films 208 with the film thickness of 4 nm are formed on the semiconductor substrate 201 and the side walls of the P-doped polysilicon films 203 which are used as active areas through the silicon oxide film 207 by radical oxidation. The radical oxidation process is performed by heating the substrate to 900° C. or more, supplying hydrogen and oxygen in a low-pressure atmosphere and reacting them with each other on the substrate. In this embodiment, the radical oxidation process was performed in such a film formation condition that a film was formed to 4 nm at 950° C. on a test piece. The silicon oxide films 208 formed by oxidizing the underlying semiconductor substrate 201 and P-doped polysilicon film 203 become films with a higher density in comparison with the silicon oxide film 207 formed by deposition by use of the CVD method.

The radical oxidation process is performed by use of active oxygen, which is an oxidizing agent, through the silicon oxide film 207. As described in the first embodiment, if the active oxygen is diffused to the depth of 30 nm or more in the silicon oxide film formed by the CVD method, the active oxygen is deactivated. That is, the active oxygen loses oxidation power as an oxidizing agent.

In the present embodiment, the silicon oxide film 207 is formed to have the film thickness of 15 nm which is less than 30 nm, but the initial trench width of the isolation trench 206-1 of the memory cell portion is 32 nm. Therefore, as shown in FIG. 19, the internal portion of the isolation trench 206-1 is almost completely filled with the silicon oxide film 207.

Since the oxidizing agent can reach the side walls of the active area without being deactivated in the peripheral circuit portion, the oxide films 208 are formed on the side walls of the active area under the silicon oxide film 207 in the isolation trench 206-2, as shown in FIG. 20. At the same time, the oxide films 208 penetrate along the interface between the silicon thermal oxynitride film 202 and the semiconductor substrate 201 and the interface between the silicon thermal oxynitride film 202 and the P-doped polysilicon film 203 and so-called bird's beak oxide are formed. The penetration length of the bird's beak in the active area end portion in the peripheral circuit at this time is set to 10 nm as shown in FIG. 20.

However, in the memory cell portion, since the internal portion of the isolation trench 206-1 is almost completely filled with the silicon oxide film 207, active oxygen cannot reach the side walls of the active area. Therefore, part of the surface of the silicon nitride film 204 is oxidized, but portions of the silicon substrate 201 which face the isolation trenches 206-1 are almost completely unoxidized.

As described above, in the second embodiment, a thick oxide film can be formed only on the side walls of the active area of the peripheral circuit portion without substantially forming the oxide film by radical oxidation on the side walls of the active area of the memory cell portion and the end portions of the active area can be formed into a rounded form by forming the bird's beaks.

Since the active oxygen used as the oxidizing agent for radical oxidation is separated from a plasma source in comparison with the case of plasma oxidation, the active oxygen is set into an electrically neutral state although it is set into an excited state and has energy. However, like the case of plasma oxidation, the active oxygen is deactivated due to the interaction with the trench side surface in the narrow trench. Therefore, as in the present embodiment, even when non-filled portions are formed in a slit form in the cell internal portion without completely filling the internal portion of the isolation trench 206-1 with the silicon oxide film 207, substantially the same effect can be attained.

The correlation between the width of the open space in the trench after the silicon oxide film 207 is deposited and the penetration length of the bird's beaks formed along the upper and lower interfaces of the gate oxide film is shown in FIG. 7, like the case of the plasma oxidation. Therefore, also, in the case of radical oxidation, formation of the bird's beak can be suppressed by setting the width of a non-filled region of the memory cell portion after deposition of the silicon oxide film 207 (the width of the isolation trench 206-1 after deposition of the silicon oxide film 207) to 10 nm or less.

Further, in the radical oxidation process, ions of the oxidizing agent collide with one another and are deactivated under a high pressure. Therefore, it is important to make it difficult for the oxidizing agent to diffuse by narrowing the width of the non-filled region of the memory cell portion and, at the same time, suppress growth of an oxide film in the trench by selecting the above condition (high-pressure condition).

Also, in the present embodiment, the silicon oxide film 207 (liner dielectric film) is deposited without forming a thermal oxide film on the underlying layer formed of the semiconductor substrate 201 and P-doped polysilicon films 203. However, as described in the first embodiment, the semiconductor substrate 201 and P-doped polysilicon films 203 can be thermally oxidized to such an extent that bird's beaks will not cause a problem before deposition of the silicon oxide film 107.

After formation of the oxide films 208 shown in FIG. 20, a tilted ion-implantation process of B (boron) with an incident angle of 3° to 4° is performed with an area density of 1×10¹¹ cm⁻² as shown in FIG. 21. Thus, B is doped only into the side walls of the active area in the peripheral circuit portion to form diffusion layers 209. The impurity concentration of the side walls of the active area of the peripheral circuit portion can thus be enhanced by the ion-implantation process and the STI punch through voltage can be enhanced.

If the above ion-implantation process is also performed for the memory cell portion, there occurs a problem that a sufficiently large ON current of the transistor cannot be attained in the memory cell portion having an active area with a narrow width, which lowers the operation speed. However, in the present embodiment, the silicon oxide film 207 is filled only into the STI region of the memory cell portion and the ion-implantation process is performed with the silicon oxide film used as a mask. Thus, impurities are not doped into the memory cell portion but can be doped only into the peripheral circuit portion without additional lithography process.

As a result, since the threshold voltage of the transistor only in the active area end portion of the peripheral circuit portion can be enhanced, the inverse narrow channel effect due to the influence of a fixed charge of an STI filling material can be suppressed. The “inverse narrow channel effect” is a phenomenon in which the fixed charge of the STI region exerts an influence on the threshold voltage of the transistor and causes a problem in an active area with a width of approximately 1 μm.

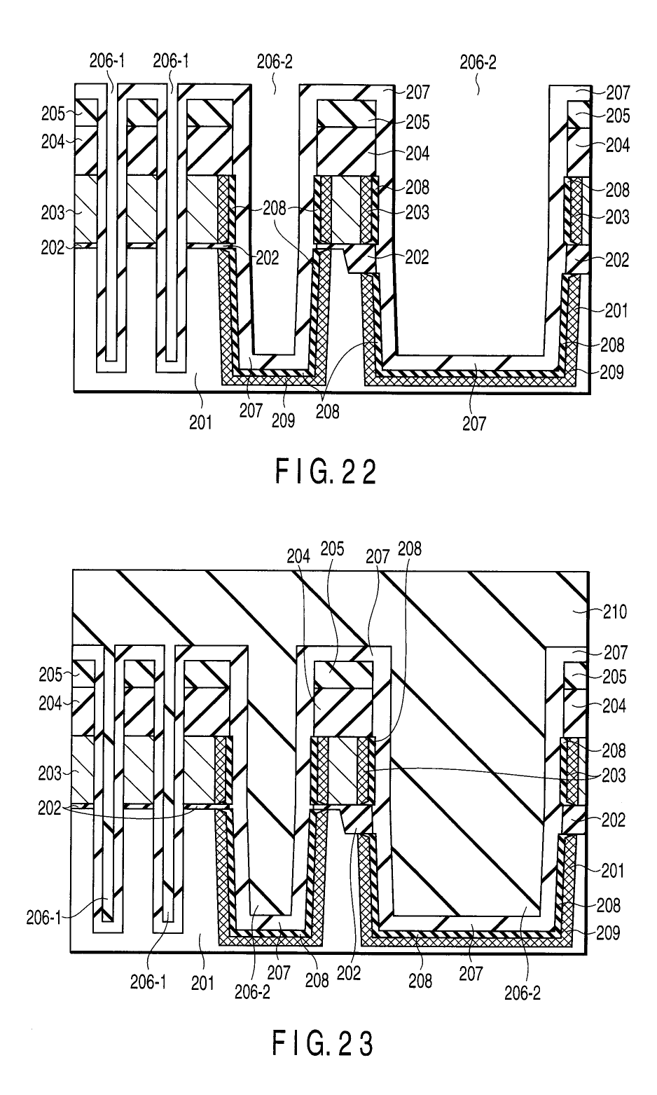

Next, as shown in FIG. 22, the seam portion (joint portion) of the silicon oxide film 207 filled in the memory cell portion is eliminated and the trenches 206-1 are opened again by etching the silicon oxide film 207 by the width of approximately 5 nm by wet etching.

Next, as shown in FIG. 23, a polysilazane film 210 is formed on the entire surface of the resultant semiconductor structure to be completely filled into the isolation trenches 206-1 and 206-2. The film formation method and conditions of the polysilazane film 210 are the same as those of the first embodiment.

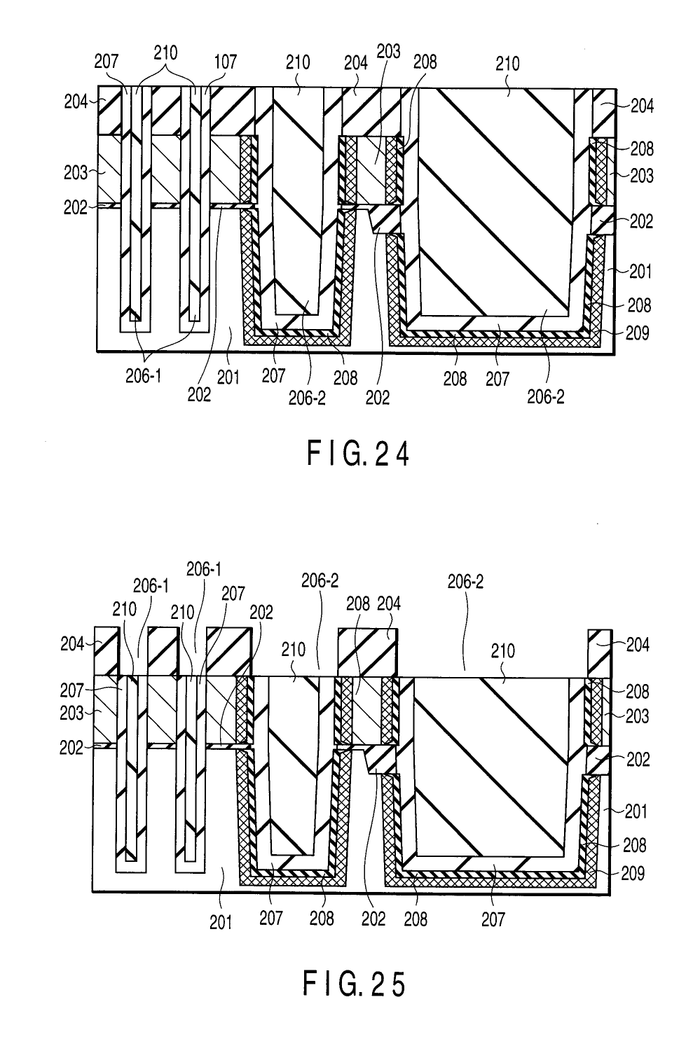

Next, as shown in FIG. 24, the CVD silicon oxide film 205, silicon oxide film 207 and polysilazane film 210 are polished by use of a CMP technique with a silicon nitride film 204 used as a stopper. As a result, the polysilazane films 210 remain only in the internal portions of the isolation trenches 206-1 and 206-2.

Then, as shown in FIG. 25, the gap-fill films (silicon oxide film 207 and polysilazane film 210) remaining in the internal portions of the isolation trenches 206-1 and 206-2 are etched back by 100 nm by reactive ion etching.

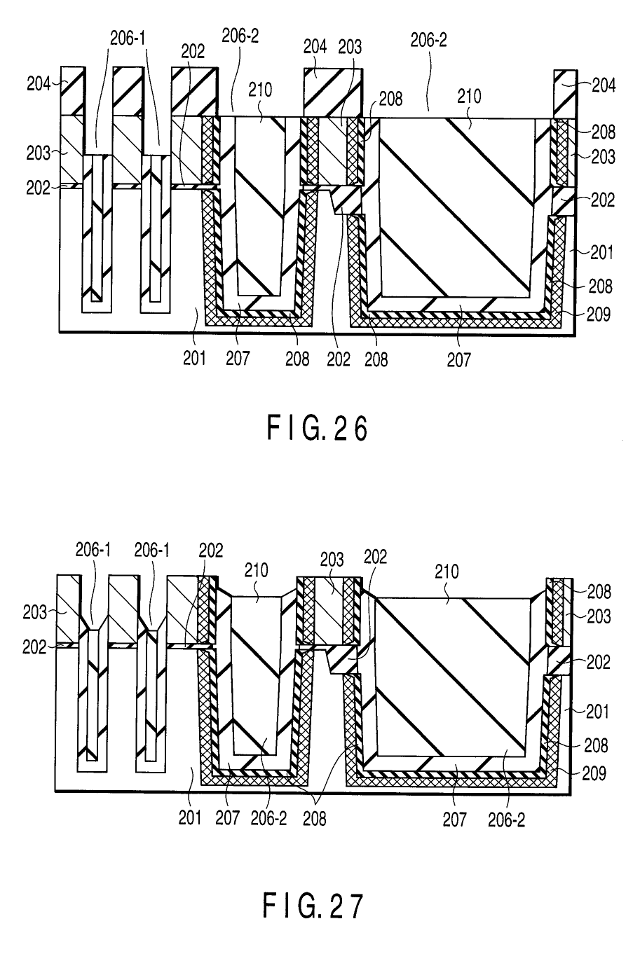

Further, as shown in FIG. 26, the internal portions of the isolation trenches 206-1 used as the STI regions of the memory cell portion are further etched by 60 nm by use of a known lithography technique and RIE technique.

After this, as shown in FIG. 27, the STI regions in the memory cell portion and peripheral circuit portion are formed by removing the silicon nitride films 204 in hot phosphoric acid. In this case, the upper potions of the polysilazane films 210 are slightly recessed, as shown in FIG. 27, due to a difference in the etching rate of the silicon oxide film 207 and polysilazane film 210 in the hot phosphoric acid.

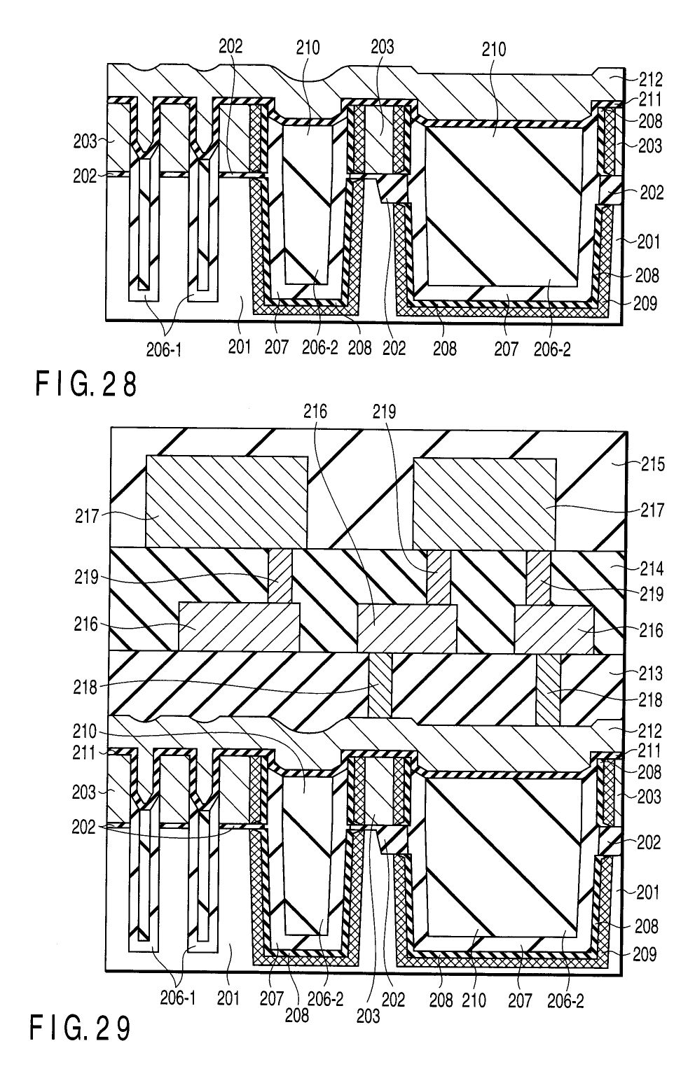

Next, as shown in FIG. 28, an ONO film 211 used as an inter-polysilicon gate dielectric film (IPD) is formed and a P-doped polysilicon film 212 used as a control gate is formed. The P-doped polysilicon film 212, ONO film 211 and P-doped polysilicon film 203 are sequentially etched by use of a known lithography technique and RIE technique to form control gates and floating gates (not shown).

After this, as shown in FIG. 29, a device with the final structure is obtained by forming interlayer dielectric films (ILD) 213, 214, 215 and a multi-layered wiring structure having wirings 216, 217, contact plugs 218, 219 although a detailed explanation of the steps is omitted.

In the present embodiment, the phenomenon that the oxidizing agent in the radical oxidation is deactivated during diffusion and the oxidation rate is rapidly lowered is utilized. That is, the oxidation process can be performed so that a thick oxide film can be formed on the side walls of the active area in the peripheral circuit portion in which the distance over which the oxidizing agent is required to diffuse is set short and the side walls of the active area in the memory cell portion in which the distance is set long can be prevented from being substantially oxidized.

In practice, in the post-process after the radical oxidation process, there is a possibility that minute bird's beaks may be formed in the memory cell portion. However, even if it is taken into consideration, the penetration depth of the bird's beak formed in the peripheral circuit portion can be made larger than the penetration depth of the bird's beak formed in the memory cell portion by use of the method of the present embodiment. As a result, an oxide structure having the shapes of the active area end portions which are different in the memory cell portion and peripheral circuit portion can be realized.

Therefore, like the first embodiment, the size of the bird's beak in the memory cell portion can be made small to prevent deterioration in the write/erase characteristic and, at the same time, the electric field concentration can be suppressed by rounding the active area end portion in the peripheral circuit portion. Thus, since a flash memory having a preferable cell characteristic and preferable peripheral circuit characteristic can be manufactured when an extremely narrow STI structure is formed, the bit density of the flash memory can be further enhanced.

In the present embodiment, the polysilazane film is used as a film which can be completely filled into the trench used as the STI region having a small width of 32 nm without forming voids. However, the STI trench with the small width can be filled by use of a different type of SOG film, for example, an HSQ (Hydrogen Silses Quioxane: HSiO_{3/2})ₙ, where n is an integral number) film or chemical vapor condensation film.

### Third Embodiment

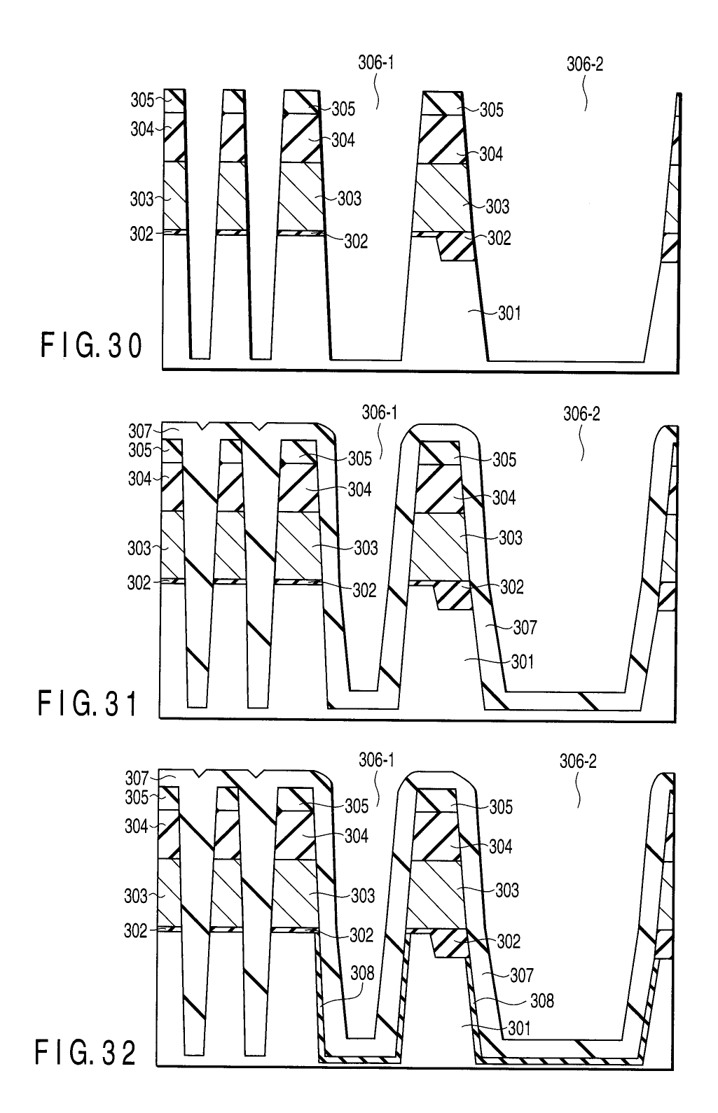

A manufacturing method of a flash memory according to a third embodiment of this invention is explained with reference to FIGS. 30 to 35. In the present embodiment, the memory cell portion of the flash memory is previously filled (or covered) with a TEOS/O₃ film, then the side walls of an active area are oxidized and an STI structure is formed.

First, a silicon thermal oxynitride film 302 used as a gate dielectric film is formed to separately have the film thickness of 8 nm (first gate dielectric film) in the memory cell portion and the film thickness of 40 nm (second gate dielectric film) in a high-voltage circuit of a peripheral circuit on a semiconductor substrate 301 by use of a known lithography process and etching process.

Then, a P-doped polysilicon film 303 (floating gate electrode layer) used as a floating gate is formed to the film thickness of 90 nm and a silicon nitride film 304 used as a polishing stopper of the CMP process is formed to the film thickness of 70 nm. Further, a CVD silicon oxide film 305 used as a mask for reactive ion etching (RIE) is formed on the entire surface of the resultant semiconductor structure and a photoresist film (not shown) is coated thereon.

Next, the photoresist film is exposed and developed by a normal lithography technique to form a photoresist pattern and the CVD silicon oxide film 305 is etched by use of an RIE process with the photoresist pattern used as a mask to form a hard mask (not shown). The photoresist pattern is etched and removed by use of both ashing and wet treatment using a mixed solution of sulfuric acid and hydrogen peroxide solution.

After this, as shown in FIG. 30, the silicon nitride film 304, P-doped polysilicon film 303, silicon thermal oxynitride film 302 and semiconductor substrate 301 are sequentially etched by use of the RIE process using the hard mask of the CVD silicon oxide film 305 to form isolation trenches 306-1 and 306-2 with the etching depth of 220 nm in the semiconductor substrate. The isolation trenches 306-1 and 306-2 configure STI regions. The STI width of the isolation trench 306-1 in the memory cell portion is set to 45 nm and the STI width of the isolation trench 306-2 in the peripheral circuit portion is set to 100 nm or more. Further, the taper angle of the isolation trench 306-1 in the memory cell portion is set to 87° or less. The taper angle is so set as to fill a TEOS/O₃ film in a seamless form, as will be described later.

Next, as shown in FIG. 31, a TEOS/O₃ film 307 (liner dielectric film) is deposited and formed with the film thickness of 25 nm on the entire surface of the resultant semiconductor structure. The film deposition temperature of the TEOS/O₃ film is 540° C. and the film deposition pressure is 600 Torr. As a result, the internal portion of the isolation trench 306-1 is almost completely filled with the TEOS/O₃ film 307 and the entire surface of the isolation trench 306-2 is covered with the TEOS/O₃ film 307.

Then, as shown in FIG. 32, silicon oxide films 308 with the film thickness of 6 nm are formed on the semiconductor substrate 301 and the side walls of the P-doped polysilicon films 303 used as active areas through the TEOS/O₃ film 307 by plasma oxidation. The measurement of the film thickness of the silicon thermal oxide film by plasma oxidation was made under a condition that the films were formed with the film thickness of 6 nm on a test piece at the temperature 450° C. by active oxygen excited by RLSA (Radial Line Slot Antenna) microwave plasma oxidation.

The plasma oxidation process is performed by use of active oxygen, which is an oxidizing agent, through the TEOS/O₃ film 307. Like the case of the silicon oxide film formed by the CVD method, if the active oxygen is diffused to the depth of 30 nm or more in the TEOS/O₃ film 307, the active oxygen is deactivated. That is, the active oxygen loses oxidation power as an oxidizing agent.

In the present embodiment, the TEOS/O₃ film 307 is formed to have the film thickness of 25 nm, which is less than 30 nm, but the initial trench width of the isolation trench 306-1 of the memory cell portion is 45 nm. Therefore, as shown in FIG. 31, the internal portion of the isolation trench 306-1 is almost completely filled with the TEOS/O₃ film 307.

Since the oxidizing agent can reach the side walls of the active area without being deactivated in the peripheral circuit portion, the oxide films 308 are formed on the side walls of the active area under the TEOS/O₃ film 307 in the isolation trench 306-2 as shown in FIG. 32. At the same time, the oxide films 308 penetrate along the interface between the silicon thermal oxynitride film 302 and the semiconductor substrate 301 and the interface between the silicon thermal oxynitride film 302 and the P-doped polysilicon film 303 and so-called bird's beaks are formed. The penetration length of the bird's beak in the active area end portion in the peripheral circuit is 13 nm.

However, in the memory cell portion, since the internal portions of the isolation trenches 306-1 are almost completely filled with the TEOS/O₃ film 307, the active oxygen cannot reach the side walls of the active area. Therefore, part of the surface of each silicon nitride film 304 is oxidized, but portions of the silicon substrate 301 which face the isolation trenches 306-1 are almost completely unoxidized.

As described above, even when the isolation trenches 306-1 of the memory cell portion are filled with the TEOS/O₃ film, a thick oxide film can be formed only on the side walls of the active area of the peripheral circuit portion without substantially forming an oxide film by plasma oxidation on the side walls of the active area of the memory cell portion and the active area edge can be formed into a rounded form by the presence of bird's beaks. Particularly, in the case of the TEOS/O₃ film, an advantage that a seamless filling portion can be formed by setting an adequate taper angle as described in the present embodiment can be attained.

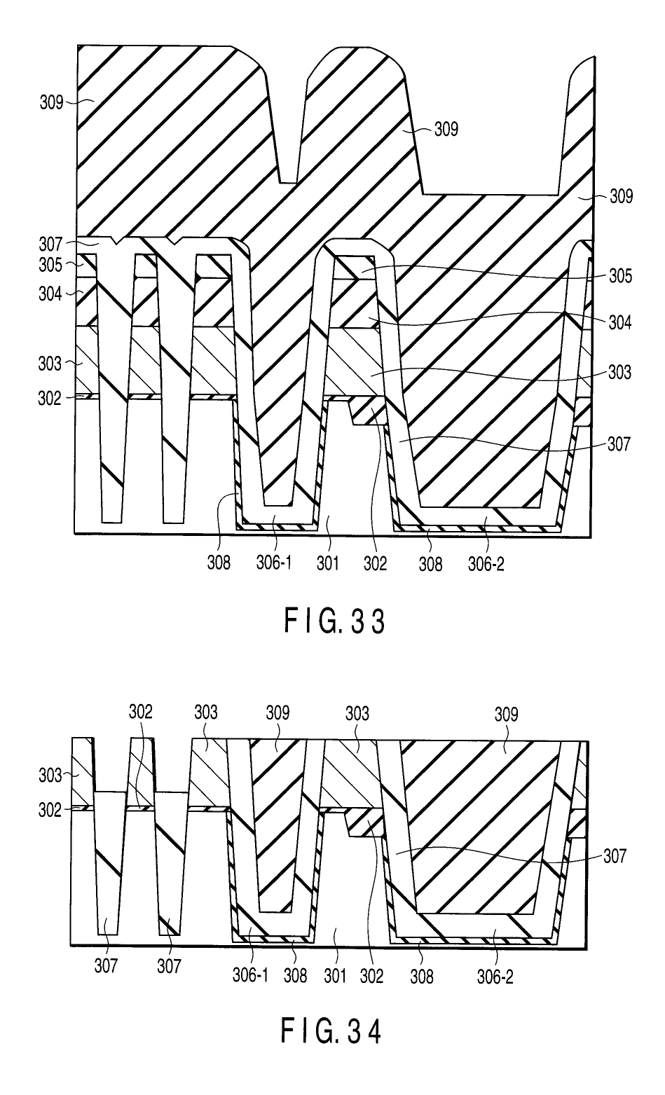

Next, as shown in FIG. 33, an HDP (high density plasma enhanced)-CVD silicon oxide film 309 is formed on the entire surface of the resultant semiconductor structure to completely fill the internal portion of the isolation trench 306-2 which is left unfilled with the TEOS/O₃ film.

In the present embodiment, the filling process is performed by use of the HDP-CVD silicon oxide film, but it is also possible to fill the trench with the TEOS/O₃ film again or fill the trench with an SOG film as shown in the first embodiment.

Next, as shown in FIG. 34, the HDP-CVD silicon oxide film 309 and TEOS/O₃ film 307 are planarized by a CMP process. Further, the gap-fill films (TEOS/O₃ film 307 and HDP-CVD silicon oxide film 309) left behind in the internal portions of the isolation trenches 306-1 and 306-2 are etched back by 70 nm by reactive ion etching and the internal portion of each isolation trench 306-1 used as the STI region of the memory cell portion is further etched back by 50 nm by the known lithography technique and RIE technique. Then, the STI regions in the memory cell portion and peripheral circuit portion are formed by removing the silicon nitride films 304 in hot phosphoric acid.

Next, an ONO film 310 used as an IPD film is formed and a P-doped polysilicon film 311 used as a control gate is formed. The P-doped polysilicon film 311, ONO film 310 and P-doped polysilicon films 303 are sequentially etched by use of a known lithography technique and RIE technique to form control gates and floating gates (not shown).

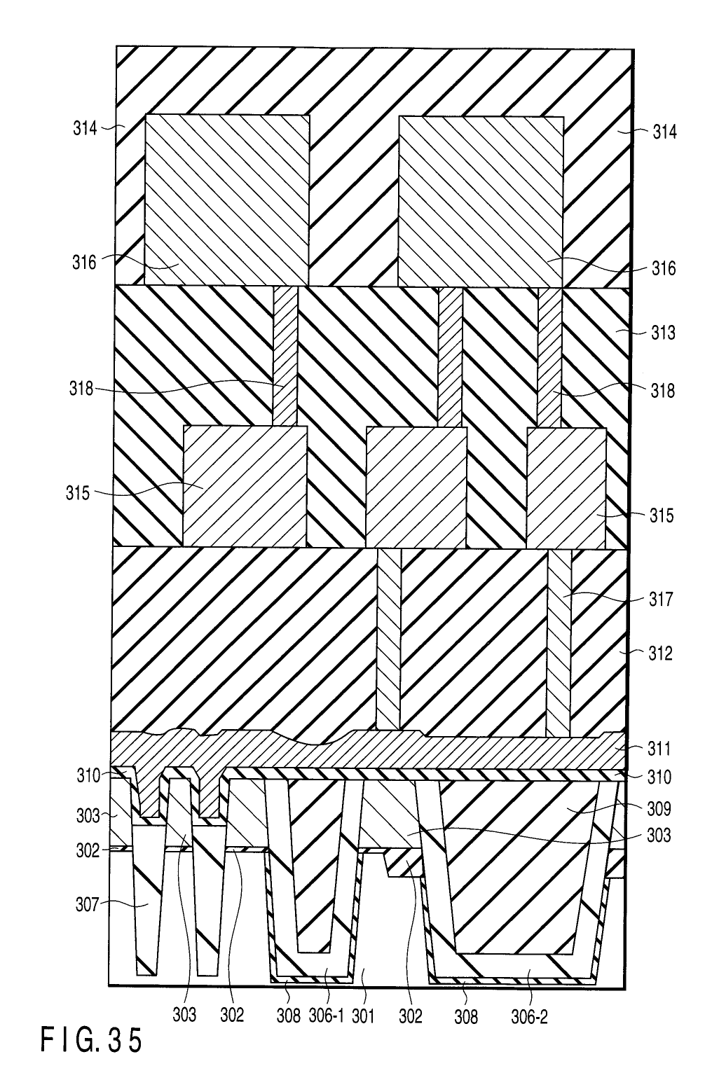

After this, as shown in FIG. 35, a device with the final structure is obtained by forming interlayer dielectric films (ILD: Inter-Layer-Dielectric) 312, 313, 314 and a multi-layered wiring structure having wirings 315, 316, contact plugs 317, 318 although a detailed explanation of the steps is omitted.

As described above, like the first and second embodiments, in the third embodiment, the size of the bird's beak oxidation in the memory cell portion can be made small to prevent deterioration in the write/erase characteristic and, at the same time, the electric field concentration can be suppressed by rounding the active area edge in the peripheral circuit portion. Thus, since a flash memory having a preferable cell characteristic and preferable peripheral circuit characteristic can be manufactured when an extremely fine STI structure is formed, the bit density of the flash memory can be further enhanced.

As described above, according to one aspect of this invention, a flash memory in which the electric field concentration in the peripheral circuit portion can be alleviated without deteriorating the element characteristic of the memory cell portion and a manufacturing method of the flash memory can be provided.

Additional advantages and modifications will readily occur to those skilled in the art. Therefore, the invention in its broader aspects is not limited to the specific details and representative embodiments shown and described herein. Accordingly, various modifications may be made without departing from the spirit or scope of the general inventive concept as defined by the appended claims and their equivalents.

What is claimed is:

1. A flash memory comprising:
a memory cell portion having first gate dielectric films formed on a main surface of a semiconductor substrate and floating gate electrode layers formed on the first gate dielectric films, and
a peripheral circuit portion having second gate dielectric films formed on the main surface of the semiconductor substrate and gate electrode layers formed on the second gate dielectric films,
wherein a penetration depth of a bird's beak oxide formed in contact with upper and bottom surfaces of the second gate dielectric film is larger than a penetration depth of a bird's beak formed in contact with upper and bottom surfaces of the first gate dielectric film.

2. The flash memory according to claim 1, wherein an oxide of an active area end portion in the memory cell portion is different shape from an oxide of an active area end portion in the peripheral circuit portion.

3. The flash memory according to claim 2, wherein the active area end portions are formed in a rounded form by the presence of the bird's beaks.

4. The flash memory according to claim 1, further comprising thicker oxide films formed on active area side walls in the peripheral circuit portion.

5. The flash memory according to claim 1, further comprising inter-polysilicon gate dielectric films formed on the floating gate electrode layers in the memory cell portion, and control gate electrode layers formed on the inter-polysilicon gate dielectric films.

6. The flash memory according to claim 1, further comprising first gap-fill films filled in first isolation trenches formed in the memory cell portion and second gap-fill films filled in second isolation trenches formed in the peripheral circuit portion.

7. A manufacturing method of a flash memory comprising:
forming first isolation trenches and second isolation trenches having a larger width in a gate width direction than the first isolation trenches in a main surface of a semiconductor substrate, the first isolation trenches being used for element isolation in a memory cell portion having first gate dielectric films and floating gate electrode layers and the second dielectric trenches being used for element isolation in a peripheral circuit portion having second gate dielectric films and gate electrode layers,
depositing a liner dielectric film to at least partly fill the first isolation trenches and partly fill the second isolation trenches,
making a penetration depth of a bird's beak oxide formed in contact with upper and bottom surfaces of the second gate dielectric film larger than a penetration depth of a bird's beak formed in contact with upper and bottom surfaces of the first gate dielectric film by oxidizing the semiconductor substrate and gate electrode layers via the liner dielectric film deposited in the second isolation trenches to form silicon oxide films, and
forming a gap-fill film on the liner dielectric film after forming the silicon oxide films.

8. The manufacturing method of the flash memory according to claim 7, wherein the oxidation for forming the silicon oxide films via the liner dielectric film is plasma oxidation.

9. The manufacturing method of the flash memory according to claim 7, wherein the oxidation for forming the silicon oxide films via the liner dielectric film is radical oxidation.

10. The manufacturing method of the flash memory according to claim 7, wherein film thickness of the liner dielectric film in the first and second isolation trenches is not larger than 30 nm and a width of the remaining open space of the first isolation trench in the gate width direction after deposition of the liner dielectric film is not larger than 10 nm.

11. The manufacturing method of the flash memory according to claim 10, wherein trench widths of the first isolation trench in the memory cell portion and the second isolation trench are not larger than 60 nm.

12. The manufacturing method of the flash memory according to claim 7, further comprising implanting ions into side walls of the second isolation trenches after deposition of the liner dielectric film and before formation of the gap-fill film on the liner dielectric film.

13. The manufacturing method of the flash memory according to claim 12, wherein the ion implantation into the side walls is performed by using a liner dielectric film used as a mask when active area side walls are subjected to radical oxidation also as an tilted ion-implantation mask.

14. The manufacturing method of the flash memory according to claim 12, wherein the implanting ions into the side walls comprises ion-implanting impurities to enhance threshold voltage of a transistor in the active area edge of the peripheral circuit portion.

15. The manufacturing method of the flash memory according to claim 12, wherein forming the gap-fill film comprises filling the second isolation trenches with a gap-fill film having fluidity at a film deposition.
